(19) United States
(12) Patent Application Publication
(10) Pub. No.: US 2012/0075789 A1
(43) Pub. Date: Mar. 29, 2012

(54) SWIVELING BASE FOR A PORTABLE COMPUTING DEVICE

(75) Inventors: Ron DeCamp, Westminster, CA (US); Dat M. Dang, Westminster, CA (US)

(73) Assignee: TARGUS GROUP INTERNATIONAL, INC., Anaheim, CA (US)

(21) Appl. No.: 13/246,552

(22) Filed: Sep. 27, 2011

Related U.S. Application Data
(60) Provisional application No. 61/387,379, filed on Sep. 28, 2010.

(51) Int. Cl. G06F 1/16; H05K 7/00

(52) U.S. Cl. 361/679.26; 248/346.03

(57) ABSTRACT

Swiveling bases for portable computing devices are disclosed. A swiveling base can include a base member and a rotatable member. The base member can be placed on a flat surface and rotatably supports the rotatable member. The rotatable member releasably secures the portable computing device and can rotate relative to the base member to reorient a display of the portable computing device. The swiveling bases may further include a control component disposed on the base member. The control component is disposed on the base member and facilitates user interaction with a computing application being executed on the portable computing device. The control component may be, for example, a button, a joystick, a D-pad, a tactile sensor pad, a touch-sensitive D-pad, a spherical trackball, a slider, or a sliding disk.

### RELATED APPLICATIONS

This application claims the benefit under 35 U.S.C. §119(e) of U.S. Provisional Patent Application No. 61/387,379, filed Sep. 28, 2010, and entitled “GAMING CONTROLLER FOR A HANDHELD ELECTRONIC DEVICE,” which is hereby incorporated by reference herein in its entirety.

### TECHNICAL FIELD

The present disclosure relates generally to cases and stands for portable computing devices, and more particularly to a swiveling base for a portable computing device.

### BRIEF DESCRIPTION OF THE DRAWINGS

The written disclosure herein describes illustrative embodiments that are non-limiting and non-exhaustive. Reference is made to certain of such illustrative embodiments that are depicted in the figures, in which:

FIG. 1 illustrates a partially cut-away perspective view of a swiveling base, according to one embodiment of the present disclosure.

FIG. 2 illustrates a perspective view of a swiveling base, according to another embodiment of the present disclosure.

FIG. 3 illustrates another perspective view of the swiveling base of FIG. 2.

FIG. 4 illustrates a top view of the swiveling base of FIG. 2.

FIG. 5 illustrates a side partial sectional view of the swiveling base of FIG. 2.

FIG. 6 illustrates a perspective view of a swiveling base, according to another embodiment of the present disclosure.

FIG. 7 illustrates another perspective view of the swiveling base of FIG. 6.

FIG. 8 illustrates a top view of the swiveling base of FIG. 6.

FIG. 9 illustrates a side view of the swiveling base of FIG. 6.

FIG. 10 illustrates a perspective view of a swiveling base, according to another embodiment of the present disclosure.

FIG. 11 illustrates a bottom perspective view of a swiveling base, according to another embodiment of the present disclosure.

FIG. 12 illustrates a perspective view of the swiveling base of FIG. 11.

FIG. 13 illustrates a side view of the swiveling base of FIG. 11.

FIG. 14 illustrates another perspective view of the swiveling base of FIG. 11

FIG. 15 illustrates another perspective view of the swiveling base of FIG. 11, in a closed configuration.

### DETAILED DESCRIPTION OF PREFERRED EMBODIMENTS

The proliferation of handheld and other portable computing devices, including notebook and tablet computers, PDAs, and smart phones, has placed more computing power into the hands of users than the computing power of early computers that occupied an entire room. This portable computing power has also enhanced mobile gaming.

The gaming made possible by portable computing devices is not limited to traditional video games. More and more, portable computing devices are used to play more traditional games, such as card games and board games. Groups of people gather around a table and pull out a portable computing device, such as a laptop, table computer, or iPad, rather than a box containing cards or a game.

The present disclosure provides embodiments of swiveling bases that can be used, for example, to enhance a gaming experience on a portable computing device. For example, the swiveling base may enhance gaming for groups of people by enabling rotation of the game (i.e., the portable computing device) to an orientation appropriate for a given player. The swiveling base can also supplement or replace touch-screen technology during gaming, or otherwise provide functionality not possible with touch-screen technology alone. In some embodiments, the portable computing device can easily be inserted into and removed from the swiveling base.

The embodiments disclosed herein are described in terms of their use for enhancing gaming on a portable computing device. As can be appreciated, the scope of the disclosure is not so limited and the embodiments disclosed herein can be adapted for a variety of purposes and uses with portable computing devices.

The term “portable computing device” is a broad term that is used herein in its ordinary sense and includes, but is not limited to, such devices as tablet computers (e.g., the Apple® iPad™), smart phones (e.g., the Apple® iPhone®, the Motorola® Droid®, the BlackBerry® Storm™, and the like), personal digital assistants (PDAs) and electronic book readers (e.g., the Amazon® Kindle™, the Barnes & Nobel Nook™). In the illustrated embodiments, the computing device 10 may be an iPad. An ordinarily skilled artisan appreciates the disclosed embodiments are not limited to use with an iPad, but may be configured for another portable computing device.

Embodiments may be best understood by reference to the drawings, wherein like parts are designated by like numerals throughout. It will be readily understood that the components of the present disclosure, as generally described and illustrated in the drawings herein, could be arranged and designed in a wide variety of different configurations. Thus, the following more detailed description of the embodiments of the apparatus is not intended to limit the scope of the disclosure, but is merely representative of possible embodiments of the disclosure. In some cases, well-known structures, materials, or operations are not shown or described in detail.

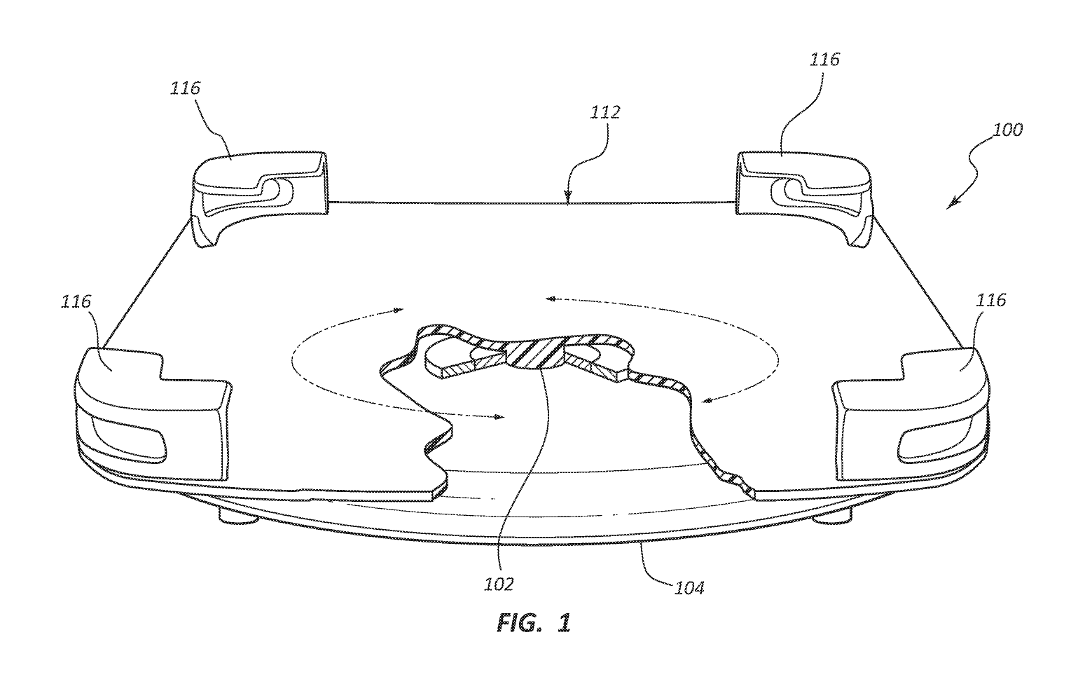

FIG. 1 illustrates a partially cut-away perspective view of a swiveling base 100, according to one embodiment of the present disclosure. The swiveling base 100 may include a base member 104 and a rotatable member 102. The base member 104 may be configured to sit on a table or other flat surface and support the rotatable member 102. The rotatable member 102 may be configured to rotate relative to the base member 104 within a plane parallel to the plane of the table or flat surface. In the illustrated embodiment, the rotatable member 102 may be a post rotatably coupled to the base member 104. The rotatable member 102 may be rotatably coupled to the base member 104 using any appropriate rotatable coupling or mechanism, including but not limited to a bushing, a flanged bushing, a grommet, a rivet, plain bearings, bearings, and/or any combination thereof.

The rotatable member 102 may include and/or be coupled to a securement mechanism 112 configured to secure a portable computing device, such as an iPad, to the rotatable member 102. The securement mechanism 112 may secure the portable computing device in a manner that the portable computing device is fixed relative to the rotatable member 102 and rotates relative to the base member 104 as the rotatable member 102 rotates. The securement mechanism 112 may include corner clips 116 each configured to receive a corner of the portable computing device.

The swiveling base 100 provides the ability to reorient the portable computing device during a multiplayer game, such as a board game, so that the currently active player can view the screen of the portable computing device in a proper orientation during the player's turn. When secured to the rotatable member 102 of the swiveling base 100, the portable computing device can be easily rotated to an appropriate orientation for the next player.

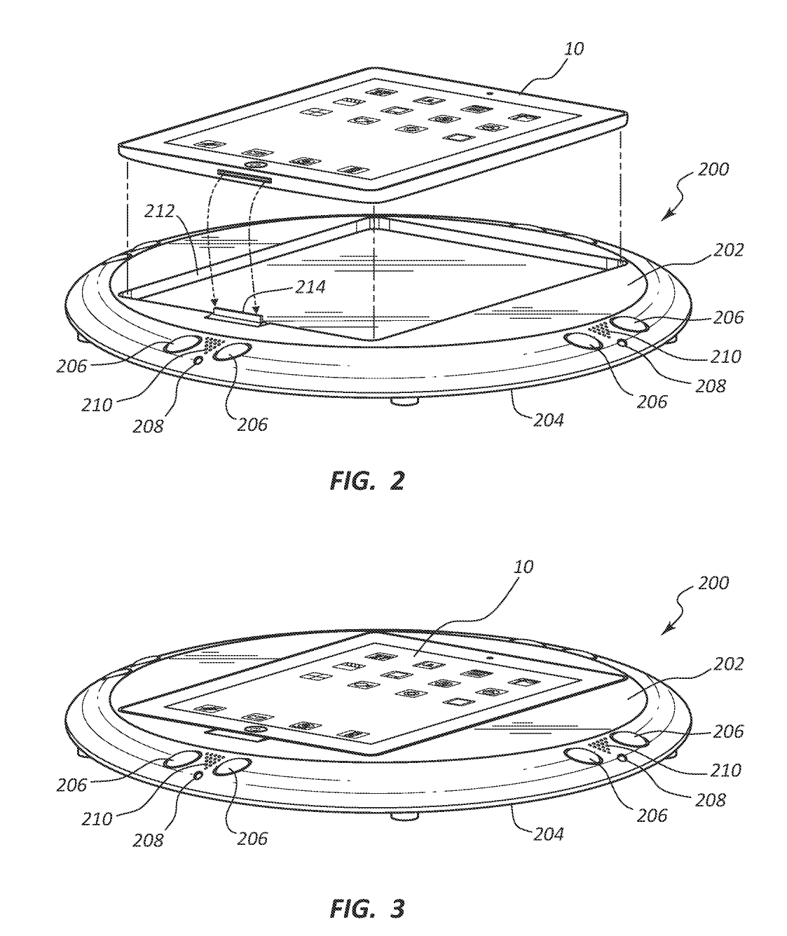

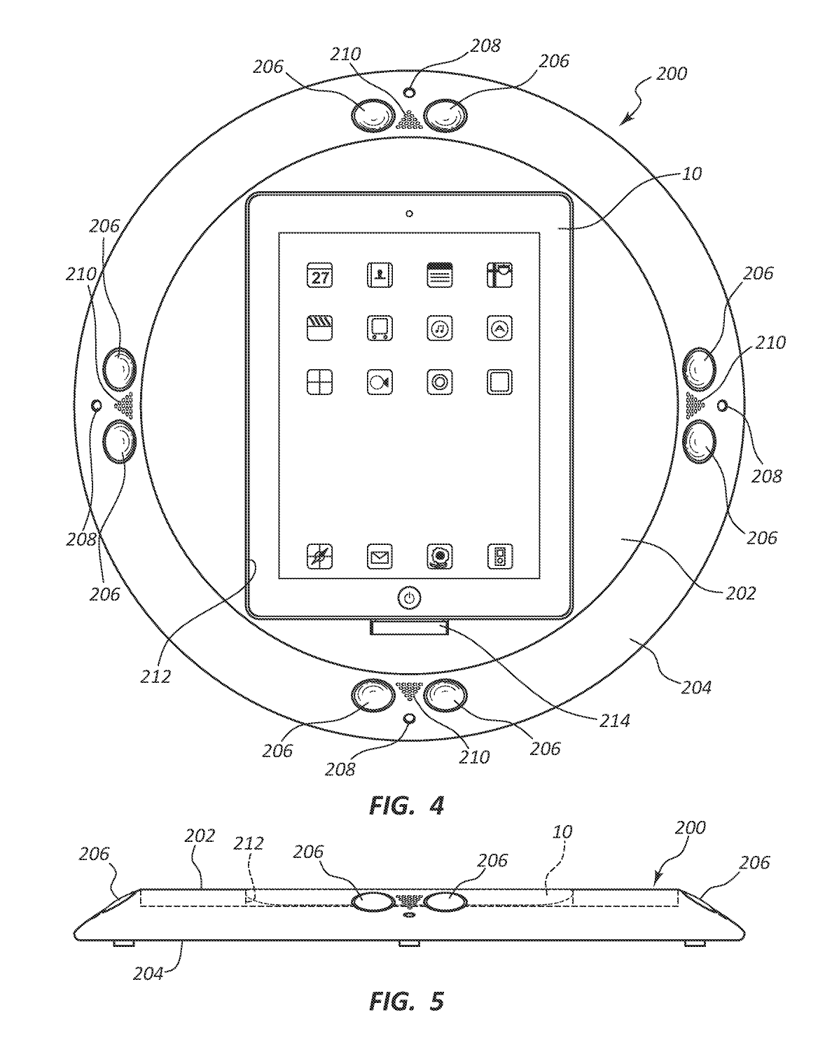

FIGS. 2-5 illustrate a swiveling base 200, according to another embodiment of the present disclosure. FIG. 2 illustrates a perspective view of the swiveling base 200. FIG. 3 illustrates another perspective view of the swiveling base 200. FIG. 4 illustrates a top view of the swiveling base 200. FIG. 5 illustrates a side partial sectional view of the swiveling base 200.

Referring collectively to FIGS. 2-5, the swiveling base 200 may comprise a base member 204 and a rotatable member 202. The base member 204 may be configured to sit on a table or other flat surface and support the rotatable member 202. The rotatable member 202 may be configured to rotate relative to the base member 204 within a plane parallel to the plane of the table or flat surface, similar to the operation of a Lazy Susan.

The rotatable member 202 may be recessed into the base member 204, as shown best in FIG. 5. An iPad 10 can rest upon or be secured to the rotatable member 202, such that the iPad 10 is fixed relative to the rotatable member 202 and rotates relative to the base member 204 as the rotatable member 202 rotates. In the illustrated embodiment, the rotatable member 202 may provide a recess 212 configured to receive and secure the iPad 10, such that the touch screen of the iPad 10 is flush or nearly flush with a top surface of the rotatable member 202 and/or the base member 204. The recess 212 secures the iPad 10 relative to the rotatable member 202 such that the iPad 10 rotates with the rotatable member 202 relative to the base member 204. The swiveling base 200 provides the ability to reorient the iPad 10 during a multiplayer game, such as an electronic board game, so that the currently active player can view the screen of the iPad 10 in a proper orientation during the player's turn. The iPad 10 can then be easily rotated, for example manually, electrically, and/or mechanically, to an appropriate orientation for the next player.

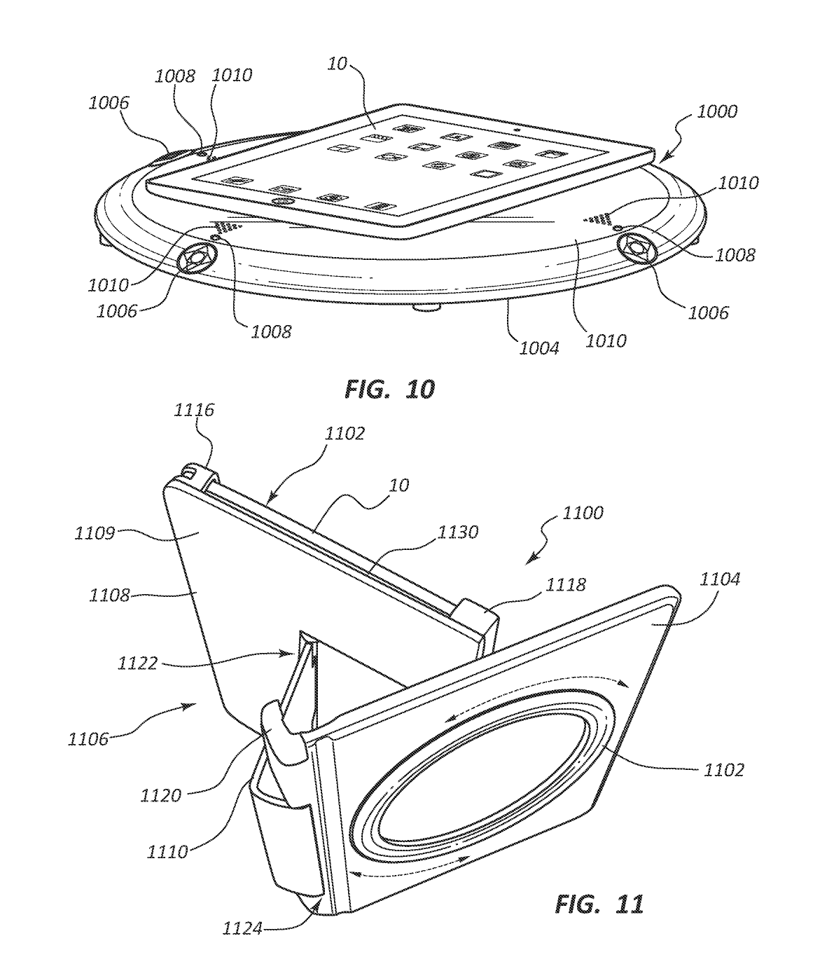

The base member 204 may further comprise control components, such as buttons 206, which may enable player interaction with the game on the iPad 10. The base member 204 may further comprise lights 208, such as LED lights, which may communicate information to players, such as which player's turn it is to play the game. For example, a light 208 may be lit in front of the player whose turn it is, at which point the rotatable member 202 may be rotated to orient a display of the iPad 10 in the appropriate direction for that player. The base member 204 may further comprise speakers 210 to provide audio of the game. The base member 204 may also comprise other components. For example, the base may include one or more control components, such as a joystick, tactile sensor, etc., to enable user interaction with the game (see FIG. 10). As can be appreciated, the buttons 206 and/or a joystick may be programmable. For example, a user may be enabled to define functionality of a button 206 and/or joystick. Still other embodiments may include any suitable directional control component, including but not limited to a joystick, a D-pad, a tactile sensor pad, a touch-sensitive D-pad, a spherical trackball, a slider and a sliding disk.

The base member 204 may further comprise a locking mechanism to lock the rotatable member 202 relative to the base member 204 in any of the various orientations. In some embodiments, the buttons 206 and/or lights 208 may be configured such that each button 206 or light 208, or set of buttons 206 or set of lights 208, corresponds to a particular orientation (rotational position) of the rotatable member 202. In some such embodiments, the swiveling base 200 may be configured to illuminate a particular light 208 to indicate whose turn it is in the game.

In one embodiment, the base member 204 may include a connector 214 to interface to the iPad 10. For example, the connector 214 may be integrated with the rotatable member 202 and may, for embodiments configured to be used with an iPad 10, be a spring-loaded 30-pin connector 214 configured to connect to the iPad 10. The connector 214 may facilitate the swiveling base 200 communicating with the iPad 10 to transmit signals to the iPad 10 indicating the manner that, for example, a joystick is manipulated or that a particular button 204 has been activated. These signals can then be sent to the game on the iPad 10 to provide interaction with or control in the game environment. The connector 214 may also function to lock the iPad 10 into position, securing it in or to the rotatable member 202. For example, in the case of a spring-loaded 30-pin connector 214, the iPad 10 may be locked into place until such time as the springs in the spring-loaded connector are compressed, which may be accomplished by, for example, withdrawing or pulling the iPad 10 in a direction away from the connector 214 or, alternatively, by actuating a separate release mechanism by way of a button, switch, or other actuation element.

In another embodiment, the connector 214 may comprise a wireless connection device, rather than an electro-mechanical connector. For example, the connector 214 may comprise WiFi® technology or Bluetooth® technology configured to wirelessly connect the iPad 10 and the swiveling base 200. As can be appreciated, the connector 214 may comprise any appropriate wireless connectivity technology.

The rotatable member 202 and/or the base member 204 may further enclose and house electronic circuitry (not shown) of the swiveling base 200. For example, the rotatable member 202 and/or the base member 204 may define a cavity (not shown) into which electronic circuitry may be mounted. The electronic circuitry may enable functionality of the buttons 206, the lights 208, and/or the speakers 210. The electronic circuitry may enable functionality of another control component of the swiveling base 200, such as a joystick. The circuitry may also enable electrical connectivity of the connector 214. The rotatable member 202 and/or the base member 204 may also house a power source, such as a battery or connection to a wall outlet.

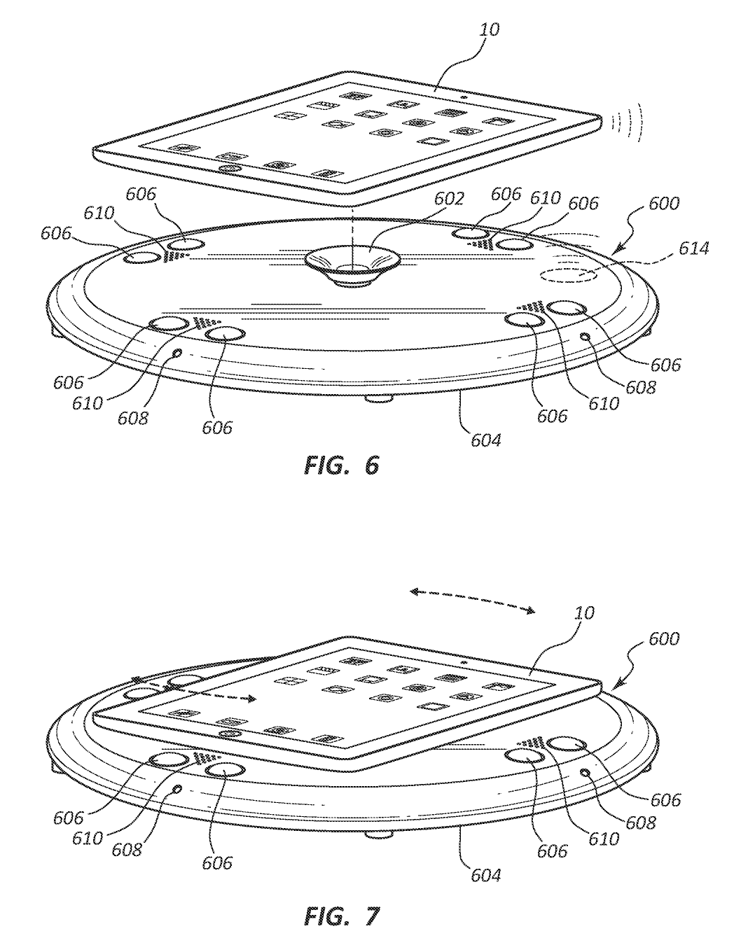

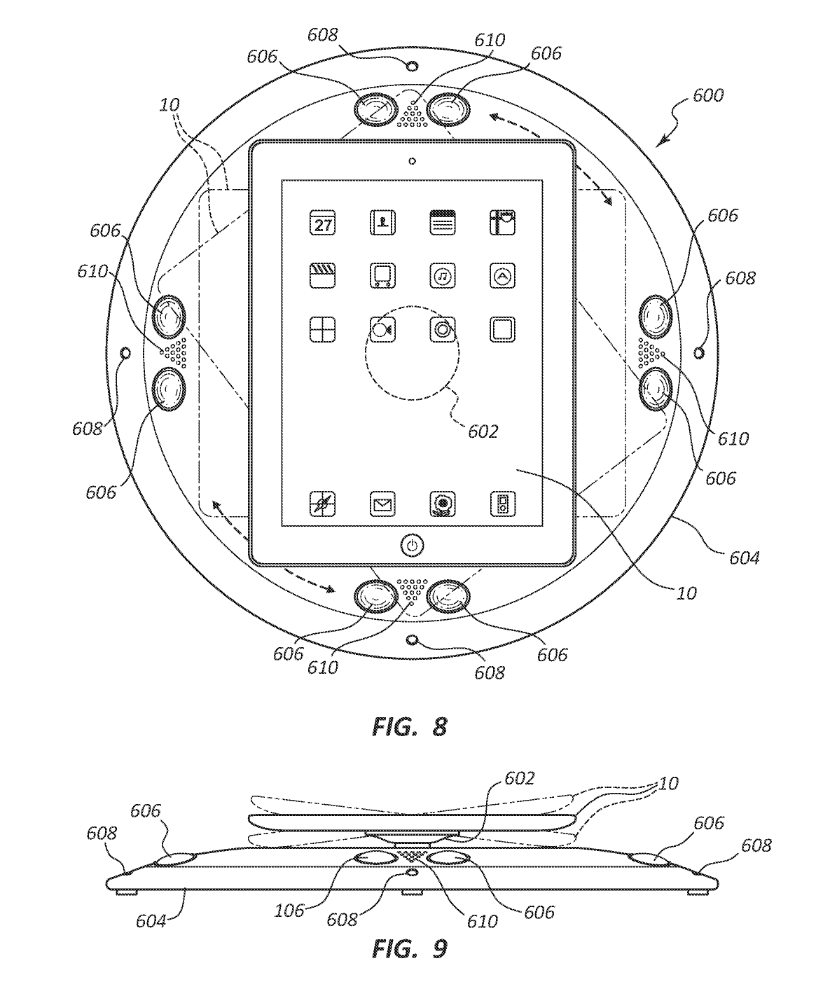

FIGS. 6-9 illustrate a swiveling base 600, according to another embodiment of the present disclosure. FIG. 6 illustrates a perspective view of the swiveling base 600. FIG. 7 illustrates another perspective view of the swiveling base 600. FIG. 8 illustrates a top view of the swiveling base 600. FIG. 9 illustrates a side view of the swiveling base 600.

Referring collectively to FIGS. 6-9, the swiveling base 600 may comprise a base member 604 and a rotatable member 602. The base member 604 may be configured to sit on a table or other flat surface and support the rotatable member 602. The rotatable member 602 may be coupled to the base member 604 and may be configured to rotate relative to the base member 604 within a plane parallel to the plane of the table or flat surface. For example, the rotatable member 602 may include (or be coupled to the base member 604 with) a ball bearing to allow the rotatable member 602 to rotate relative to the base member 604. An iPad 10 can rest upon the rotatable member 602 or be secured to the rotatable member 602 with a securement mechanism 612, such that the iPad 10 is fixed relative to the rotatable member 602 and rotates relative to the base member 604 as the rotatable member 602 rotates. The swiveling base 600 provides the ability to reorient the iPad 10 during a multiplayer game, such as a board game, so that the currently active player can view the screen of the iPad 10 in a proper orientation during the player's turn. The iPad 10 can then be easily rotated, either manually, electrically, and/or mechanically, to an appropriate orientation for the next player.

In the illustrated embodiment, the securement mechanism 612 may protrude above the base member 604 to provide clearance and allow the iPad 10 to rotate with the rotatable member relative to the base member 604. The securement mechanism 612 may comprise a suction cup, as illustrated. In another embodiment, the securement mechanism 612 may comprise a bracket configured to couple to a mating bracket on a case of the iPad 10. In another embodiment, the securement mechanism 612 may comprise a hook and loop securement device, such as Velcro®. As can be appreciated by a person of ordinary skill, the securement mechanism 612 can include any of a variety of securement devices that can secure an iPad 10, or other portable computing device, relative to the rotatable member 602.

The base member 604 may further comprise buttons 606, which may enable player interaction with the game on the iPad 10. The base member 604 may further comprise lights 608, such as LED lights, which may communicate information to players, such as which player's turn is active to play the game. The base member 604 may further comprise speakers 610 to provide audio of the game. The base member 604 may further comprise other components. For example, the base member 604 may include one or more control components, such as a joystick, tactile sensor, etc., to enable user interaction with the game (see FIG. 10). As can be appreciated, the buttons 606 and/or a joystick may be programmable. For example, a user may be enabled to define functionality of a button 606 and/or joystick. Still other embodiments may include any suitable directional control component, including but not limited to a joystick, a D-pad, a tactile sensor pad, a touch-sensitive D-pad, a spherical trackball, a slider and a sliding disk.

The base member 604 may further comprise a locking mechanism to lock the rotatable member 602 relative to the base member 604 in any of the various orientations. In some embodiments, the buttons 606 and/or lights 608 may be configured such that each button 606 or light 608, or set of buttons 606 or set of lights 608, corresponds to a particular rotational orientation of the rotatable member 602. In some such embodiments, the swiveling base 600 may be configured to illuminate a particular light 608 to indicate whose turn it is in the game.

The base member 604 may further enclose and house electronic circuitry (not shown) of the swiveling base 600. For example, the base member 604 may define a cavity (not shown) into which electronic circuitry may be mounted. The electronic circuitry may enable functionality of the buttons 606, the lights 608, and/or the speakers 610. The electronic circuitry may also enable functionality of a control device of the swiveling base 600, such as a joystick. The circuitry may further comprise a connector 614, such as a wireless connection device with WiFi® technology or Bluetooth® technology, configured to wirelessly connect the iPad 10 and the swiveling base 600. As can be appreciated, the connector 614 may comprise any appropriate wireless connectivity technology. The rotatable member 602 and/or the base member 604 may also house a power source, such as a battery or a connection to a wall outlet.

FIG. 10 illustrates a perspective view of a swiveling base 1000, according to another embodiment of the present disclosure. The illustrated swiveling base 1000 may have similar elements to the swiveling base 100 of FIG. 1, the swiveling base 200 of FIGS. 2-5, and/or the swiveling base 600 of FIGS. 6-9, including but not limited to a rotatable member (not shown, but see rotatable member 602 of FIG. 6) and a base member 1004. The swiveling base 1000 may also comprise a joystick 1006 in place of, or in addition to, buttons. The joystick 1006 may be configured to provide input to the iPad 10 for interaction with an application being executed (e.g., a game being played) on the iPad 10.

In other embodiments, the joystick 1006 may control manipulations of the rotatable member. For example, the joystick 1006 may activate rotation of the rotatable member and control the direction of rotation of the rotatable member. As another example, the joystick 1006 may control tilt of the rotatable member relative to the base member 1004 to play tilt games (e.g., ball maze games, rolling games, racing games).

The swiveling base 1000 may also include lights 1008 and speakers 1010.

As can be appreciated, according to other embodiments, the base member 1004 may further include various ports to facilitate interfacing with the iPad 10 when it is disposed in/on the rotatable member 1002. For example, the base member 1004 may include ports for connector plugs, cables, headphones, speakers, power adaptors, input devices (e.g., keyboard, mouse, joystick, and the like), output devices (e.g., printer, display monitor, projector, and the like), and/or other peripherals.

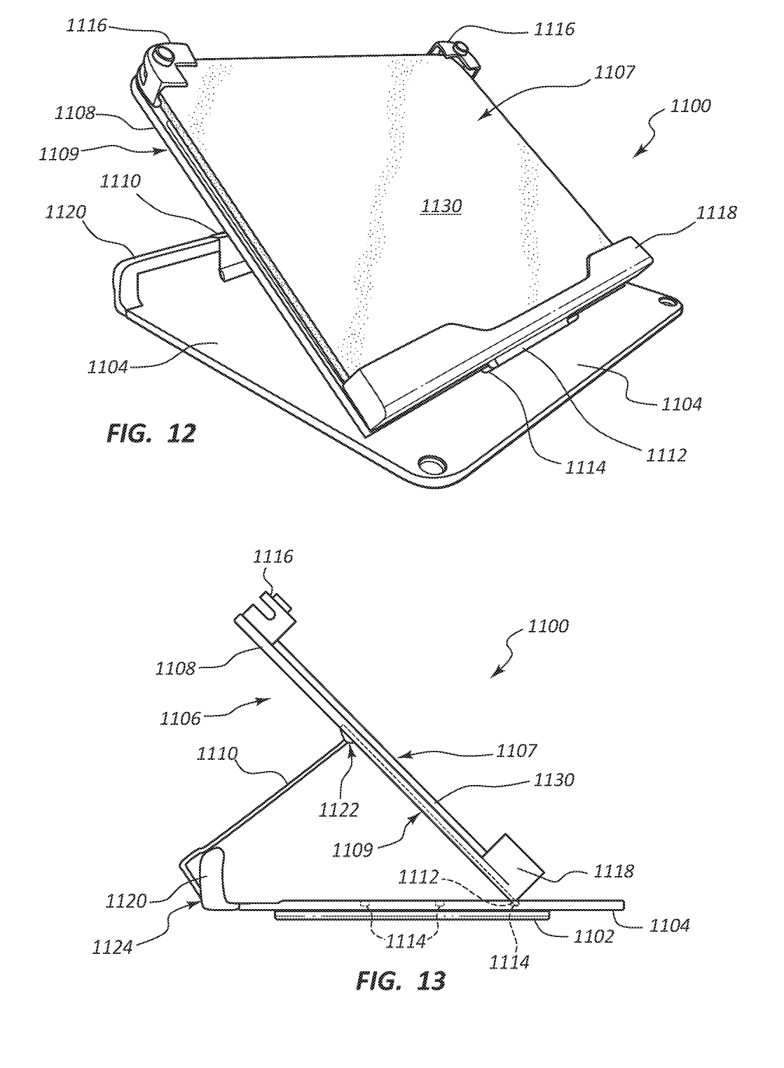

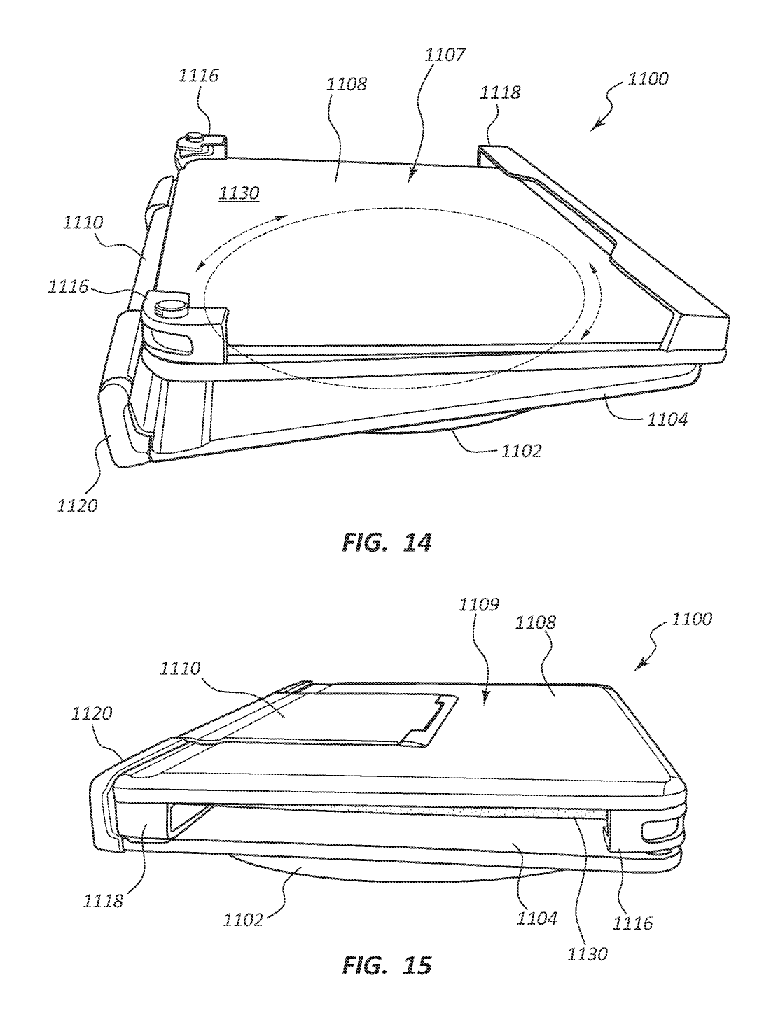

FIGS. 11-15 illustrate various views of a swiveling base 1100, according to another embodiment of the present disclosure. FIG. 11 illustrates a bottom perspective view of the swiveling base 1100. FIG. 12 illustrates a perspective view of the swiveling base 1100. FIG. 13 illustrates a side view of the swiveling base 1100. FIG. 14 illustrates another perspective view of the swiveling base 1100. FIG. 15 illustrates another perspective view of the swiveling base 1100 in a closed configuration.

Referring collectively to FIGS. 11-15, the swiveling base 1100 may include a rotatable member 1102, a base member 1104, and a stand 1106. As illustrated, the swiveling base 1100 can transition from a presentation configuration and a closed configuration. In the presentation configuration, the stand 1106 presents a display (e.g., touch screen surface) of an iPad 10 at an angle to the base member 1104 for viewing by a user, as shown in FIGS. 11-14. In the closed configuration, the swiveling base 1100 functions as a case and the iPad 10 is enclosed and protected by the swiveling base 1100 between a presentation surface 1107 of the stand 1106 and the base member 1104, as shown in FIG. 15.

The rotatable member 1102 may include a disk, ring, or other circular component that can rotate relative to the base member 1104. The rotatable member is also configured to sit on a table or other flat surface. The rotatable member 1102 may rotatably support or be rotatably coupled to the base member 1104 to enable the base member to rotate relative to the flat surface in a plane parallel to the flat surface. In other words, the base member 1104 may be configured to rotate relative to the rotatable member 1102 such that contact of the rotatable member 1102 with the flat surface restricts rotation of the rotatable member 1102 and allows rotation of the base member 1104.

The base member 1104 may comprise a rigid panel or otherwise be formed to provide a frame or support structure on which the stand 106 can rest. In the illustrated embodiment, the base member 1104 further includes one or more grooves 1114 configured to receive a catch 1112 (see FIG. 12) of the stand 1106 to facilitate adjustment of the incline of the stand 1106. The base member 1104 may also include a spine 1120 to provide structural support and to protect the iPad 10 when the swiveling base 1100 is in the closed configuration.

The stand 1106 is supported by and/or coupled to the base member 1104. The base member 1104 may enable the stand 1106 to rotate with the base member 1104 relative to the rotatable member 1102 and the flat surface about an axis perpendicular to the flat surface. The stand 1106 may include a securement mechanism 1108, to secure the iPad 10, and a support member 1110 to prop the iPad 10 and/or the securement mechanism 1108 at an angled position relative to the base member 1104 in the presentation configuration. In the illustrated embodiment, the securement mechanism 1108 may be a securement panel 1108 having one or more corner clips 1116 and a base clip 1118 configured to engage and secure the iPad 10.

The securement panel 1108 may have a presentation surface 1107 on which the iPad 10 is secured and presented and a back side 1109 coupled to the support member 1110. The corner clips 1116 and the base clip 1118 may be provided on the presentation surface 1107 to secure the iPad 10 to the presentation surface 1107. The corner clips 1116 may be configured to wrap around and/or engage corners of the iPad 10. The base clip 1118 may be configured to extend along and generally engage and secure an entire edge of the iPad 10 to firmly secure a bottom edge of the iPad 10 when the swiveling base 1100 is in the presentation configuration and to protect the bottom edge of the iPad 10 when the swiveling base 1100 is in the closed configuration. The corner clips 1116 and/or base clip 1118 may be formed of resilient flexible material that is deformable to enable insertion of the iPad into the clips 1116, 1118 for securement to the securement panel 1108. The securement panel 1108 may further include a protective layer 1130 on the presentation surface 1107. The protective layer 1130 may be configured to protect a back surface of the iPad 10 and guard against scratching or other damage to the iPad 10. The protective layer 1130 may provide a padding for shock absorption. The protective layer 1130 may also provide a thermal layer to remove heat and otherwise limit heat buildup from the iPad 10. In the illustrated embodiment, the protective layer 1130 may be, for example, neoprene or another resilient material having a nonabrasive surface.

The support member 1110 is configured to prop the securement panel 1108 in an angled position in the presentation configuration. The angle at which the securement panel 108 is propped may be adjustable. For example, the support member 1110 may prop the securement panel 108 in a relatively high inclined, angled and generally upright configuration, such as shown in FIGS. 12 and 13. The support member 1110 may also be configured to prop the securement panel 1108 at a relatively low inclined, generally horizontal configuration, such as shown in FIG. 14. The angle of the presentation surface 1107 may be adjustable in the presentation configuration between zero degrees from (parallel to) the base member 1104 and ninety degrees from (perpendicular to) the base member 1104. Adjustment of the angle of the securement panel 1108 may be accomplished by the configuration and/or structure of the support member 1110 and by the coupling of the support member 1110 to the base member 1104 and the securement panel 1108.

More specifically, the support member 1110 is elongate, extending to couple at a first end, with a first hinge 1122, to a center portion of the back side 1109 of the securement panel 1108 and to couple at a second end, with a hinge 1124, to the spine 1120 of the base member 1104. The second end may be hooked, or otherwise configured to couple with the second hinge 1124 on a bottom side of the base member 1104. The first hinge 1122 may allow the securement panel 1108 to rotate through a range of approximately 180 degrees relative to the support member 1110. Similarly the second hinge 1124 may allow the support member to rotate through a range of approximately 180 degrees relative to the base member 1104. The broad rotational ranges of the hinges 1122, 1124 may allow the securement panel 1108 to be positioned proximate to or on top of the base member 1104 with the presentation surface 1107 outward and away from the base member 1104 (in the presentation configuration presenting a display screen of the iPad) or with the presentation surface 1107 inward and toward the base member 1104 (in the closed configuration enclosing the iPad 10). In other words, the presentation surface 1107 is rotatable between a position facing outward and away from the base member 1104 and a position facing inward and toward the base member 1104.

Those having ordinary skill in the art appreciate and understand that many changes may be made to the details of the above-described embodiments without departing from the underlying principles disclosed herein. Any suitable combination of various embodiments, or the features thereof, is contemplated. Other embodiments of the present disclosure are possible. Although the description above contains much specificity, these should not be construed as limiting the scope of the disclosure, but as merely providing illustrations of some of the presently preferred embodiments of this disclosure. It is also contemplated that various combinations or sub-combinations of the specific features and aspects of the embodiments may be made and still fall within the scope of this disclosure. It should be understood that various features and aspects of the disclosed embodiments can be combined with or substituted for one another in order to form various embodiments. Thus, it is intended that the scope of at least some of the present disclosure should not be limited by the particular disclosed embodiments described above.

Throughout this specification, any reference to “one embodiment,” “an embodiment,” or “the embodiment” means that a particular feature, structure, or characteristic described in connection with that embodiment is included in at least one embodiment. Thus, the quoted phrases, or variations thereof, as recited throughout this specification are not necessarily all referring to the same embodiment. Similarly, it should be appreciated that in the above description of embodiments, various features are sometimes grouped together in a single embodiment, figure, or description thereof for the purpose of streamlining the disclosure. This method of disclosure, however, is not to be interpreted as reflecting an intention that any claim require more features than those expressly recited in that claim. Rather, inventive aspects may lie in a combination of fewer than all features of any single foregoing disclosed embodiment.

We claim:

1. A swiveling base for a portable computing device comprising:
a base member configured to be disposed on a flat surface;
a rotatable member rotatably supported by the base member, the rotatable member configured to rotate relative to the base member within a plane parallel to a plane of the flat surface;
a securement mechanism integrated with the rotatable member and configured to releasably secure the portable computing device relative to the rotatable member and to enable rotation of the portable computing device with the rotatable member and relative to the base member to reorient a display of the portable computing device.

2. The swiveling base of claim 1, wherein the securement mechanism comprises a recess in a surface of the rotatable member, the recess configured to receive the portable computing device and secure the portable computing device against lateral and rotational movement relative to the rotatable member, within the plane parallel to the plane of the flat surface.

3. The swiveling base of claim 1, wherein the securement mechanism comprises a suction cup coupled to a surface of the rotatable member.

4. The swiveling base of claim 1, further comprising a stand on the rotatable member, the stand having a presentation surface, the stand configured to prop a presentation surface in a presentation configuration, wherein a portable computing device secured to the presentation surface is presented at an angle to the base member when the presentation surface is in the presentation configuration, and wherein the securement mechanism secures the portable computing device to presentation surface of the stand.

5. The swiveling base of claim 4, wherein an angle of the presentation surface is adjustable between 0 degrees from (parallel to) the base member and 90 degrees from (perpendicular to) the base member.

6. The swiveling base of claim 4, wherein the presentation surface is configured to be rotated between a position facing outward and away from the base member and a position facing inward and toward the base member.

7. The swiveling base of claim 4, wherein the swiveling base is transitionable between:
a presentation configuration in which the stand presents the presentation surface, and a portable computing device secured thereto, at an angle to the base member; and
a closed configuration in which the portable computing device is enclosed between the presentation surface of the stand and the base member.

8. The swiveling base of claim 7, wherein the stand comprises a securement panel and a support member, the securement panel having the securement mechanism and the presentation surface, the support member having a first end coupled with a hinge to the securement panel and a second end coupled with a hinge to the base member.

9. The swiveling base of claim 4, wherein the securement mechanism comprises a plurality of resilient clips that are deformable to receive the portable computing device and that return to an original shape to secure the portable electronic device.

10. A swiveling base for a portable computing device comprising:
a base member configured to be disposed on a flat surface;
a rotatable member rotatably supported by the base member, the rotatable member configured to rotate relative to the base member within a plane parallel to a plane of the flat surface, the rotatable member configured to releasably secure the portable computing device relative to the rotatable member and to enable rotation of the portable computing device relative to the base member to reorient a display of the portable computing device; and
a control component disposed on the base member, the control component configured to facilitate user interaction with a computing application being executed on the portable computing device.

11. The swiveling base of claim 10, wherein the control component is a button.

12. The swiveling base of claim 11, wherein manipulation of the button causes an effect in the computing application being executed on the portable computing device.

13. The swiveling base of claim 11, wherein manipulation of the button causes a rotation of the rotatable member relative to the base member to reorient the display of the portable computing device.

14. The swiveling base of claim 10, wherein the control component is one of a joystick, a D-pad, a tactile sensor pad, a touch-sensitive D-pad, a spherical trackball, a slider, and a sliding disk.

15. The swiveling base of claim 14, wherein manipulation of the control component causes an effect in the computing application being executed on the portable computing device.

16. The swiveling base of claim 15, wherein the rotation of the rotatable member (relative to the base member to reorient a display of the portable computing device) comprises rotation about an axis in a plane parallel to the flat surface to cause the display to tilt relative to the flat surface.

17. The swiveling base of claim 10, wherein the control component further comprises electronic circuitry disposed in at least one of the base member and the rotatable member to implement the interaction with the computing application.

18. The swiveling base of claim 17, further comprising a connector configured to interface with the portable computing device and electronically couple the portable computing device to the electronic circuitry of the control component.

19. The swiveling base of claim 18, wherein the connector comprises a 30-pin connector configured to couple to an iPad portable computing device.

20. The swiveling base of claim 18, wherein the connector comprises wireless connectivity technology configured to wirelessly couple to the portable computing device.

21. The swiveling base of claim 10, further comprising a light disposed in the base member, the light configured to illuminate to signal information from the computing application on the portable computing device to facilitate user interaction.

22. The swiveling base of claim 10, further comprising a speaker disposed in the base member and configured to play audio provided by the computing application on the portable computing device.

23. The swiveling base of claim 10, wherein the rotatable member comprises a securement mechanism to releasably secure to the portable electronic device.

24. The swiveling base of claim 23, wherein the securement mechanism comprises a suction cup configured to secure to a back surface of the portable electronic device.

25. A swiveling base for a portable computing device comprising:
a base member configured to be disposed on a flat surface and remain in a fixed position relative to the surface during rotation of a rotatable member and portable computing device relative to the base member;
a rotatable member rotatably supported by the base member, the rotatable member configured to rotate relative to the base member within a plane parallel to a plane of the flat surface and about an axis perpendicular to the plane of the flat surface, the rotatable member configured to releasably secure the portable computing device relative to the rotatable member and to enable rotation of the portable computing device relative to the base member to reorient a display of the portable computing device;
a connector configured to interface with the portable computing device and electronically couple the portable computing device to the swiveling base; and
a control component disposed on the base member and electrically coupled to the connector, the control component configured to enable user input to a computing application being executed on the portable computing device.

26. The swiveling base of claim 25, wherein the control component is one of a button, a joystick, a D-pad, a tactile sensor pad, a touch-sensitive D-pad, a spherical trackball, a slider, and a sliding disk.
